(19) United States
(12) Patent Application Publication
(10) Pub. No.: US 2012/0064688 A1
(43) Pub. Date: Mar. 15, 2012

(54) METHOD FOR MANUFACTURING SILICON-GERMANIUM HETEROJUNCTION BIPOLAR TRANSISTOR

(76) Inventors: Fan Chen, Shanghai (CN); Xionbing Chen, Shanghai (CN); Zhengliang Zhou, Shanghai (CN)

(21) Appl. No.: 13/229,570

(22) Filed: Sep. 9, 2011

(30) Foreign Application Priority Data
Sep. 9, 2010 (CN) 201010277649.X

(51) Int. Cl. H01L 21/331

(52) U.S. Cl. 438/312; 257/E21.371

(57) ABSTRACT

A manufacturing method of a SiGe HBT is disclosed. Alter an emitter region is formed, an ion implantation is performed with a tilt angle to a base region by using an extrinsic base ion implantation process; boron ions are implanted during the extrinsic base ion implantation with an implantation dose from 1e15 to 1e16 cm⁻², an implantation energy from 5 to 30 KeV, and a tilt angle from 5 to 30 degrees. The tilt angle enables the implantation of P-type impurities into the part of the intrinsic base region at the bottom of the emitter window dielectric layer as well as the extrinsic base region, so that the base region excluding the part of the intrinsic base region in contact with the emitter region is entirely doped with P-type impurities, thus reducing the base resistance and improving the frequency characteristic of a transistor without needing to reduce its size.

### CROSS-REFERENCES TO RELATED APPLICATIONS

This application claims the priority of Chinese patent application number 201010277649.X, tiled on Sep. 9, 2010, the entire contents of which are incorporated herein by reference.

### TECHNICAL FIELD

The present invention elates to a manufacturing method of a semiconductor integrated circuit, and in particular, relates to a manufacturing method of a silicon-germanium heterojunction bipolar transistor (SiGe HBT),

### BACKGROUND OF THE INVENTION

With the increasing maturity of silicon-germanium (SiGe) process, radio-frequency (RF) circuit integration is becoming increasingly commonplace. Such modules as RF receiver, RF transmitter, switch and so on have a tendency towards integration. Therefore, both a low noise amplifier (LNA) for amplifying received signals and a power amplifier (PA) for amplifying the signals to be transmitted should be fabricated on an identical chip, and the maximum oscillation frequency (Fₘₐₓ) of a bipolar transistor should be maximized according to the following formula in order to improve its operating frequency:

$${F}_{max} = {( \frac{{f}_{t}}{8 π {r}_{b} {C}_{d BC}} )}^{1 / 2}$$

Where, fₜ is the characteristic frequency of the bipolar transistor; r_{b} is its base resistance; C_{dBC} is its BC (base-collector) capacitance. It can be found from the above formula that, in order to increase Fₘₐₓ, r_{b} and C_{dBC} should be greatly reduced.

FIG. 1 is a cross-sectional diagram showing the structure of an existing SiGe HBT formed P-type silicon substrate; an active area is isolated by field oxide regions. The existing SiGe HBT comprises:

A collector region, shown as N-collector region in FIG. 1, composed of an N-type ion implantation region formed in the active area. The collector region has a depth larger than that of the bottom of the field oxide regions and the collector region laterally extends into the bottom of the field oxide regions on both sides of the active area.

Pseudo buried layers, shown as N+ pseudo buried layers in FIG. 1, composed of N-type ion implantation regions formed at the bottom of the field oxide regions on both sides of the active area. Each pseudo buried layer is separated by a lateral distance from the active area in a lateral direction, and is in contact with the collector region which laterally extends into the bottom of the field oxide regions. The electrodes of the collector region are picked up through deep hole contacts formed on top of the pseudo buried layers in the field oxide regions.

A base region, shown as SiGe base region in FIG. 1, composed of a P-type SiGe epitaxial layer formed on the silicon substrate. The base region comprises an intrinsic base region which is formed on top of the active area and forms a contact with the collector region, and an extrinsic base region which is formed on top of the field oxide regions and is used for forming the base electrode, wherein the intrinsic base region is determined by a base window with a size larger than or equal to that of the active area, and the intrinsic base region is formed in the base window; the extrinsic base region is isolated from the field oxide regions by a base window dielectric layer.

An emitter region, shown as N+ polysilicon emitter region in FIG. 1, composed of an N-type polysilicon formed on top of the intrinsic base region and forming a contact with the intrinsic base region, wherein the emitter region is determined by an emitter window with a size smaller than that of the active area; the part of the emitter region within the emitter window contacts with the intrinsic base region, while the part of the emitter region outside the emitter window is isolated from the intrinsic base region by an emitter window dielectric layer.

The existing SiGe HBT shown in FIG. 1 has a metal silicide (not shown) formed on its surface to effectively reduce the r_{b} of the transistor, and so as to obtain a relatively ideal Fₘₐₓ. However, it should be noticed that, from the pick-up of the base region to the emitter region, other than the area that is coated with the metal silicide, there is also an area remaining uncoated by the metal silicide, namely the intrinsic base region at the bottom of the emitter window dielectric layer. The resistance of the intrinsic base region at the bottom of the emitter window dielectric layer equals to the intrinsic resistance of the SiGe epitaxial layer, the sheet resistance of which could be several thousands of ohms per square. The most common method of reducing the resistance of the intrinsic base region at the bottom of the emitter window dielectric layer is to form a transistor by a self-aligned process, but this method will increase process complexity. Another method is to reduce the width of the emitter region that laterally extends from the emitter window, i.e., the width of the emitter window dielectric layer, to reduce the resistance of the intrinsic base region at the bottom of the emitter window dielectric layer. Although this method has a relatively good effect, a high-level lithography machine must be used to perform the photoetching of the polysilicon emitter due to the reduced size of the polysilicon emitter and the high requirement of alignment accuracy. Experiments have proven that, when the width of the emitter region that laterally extends from the emitter window increases from 0.1 μm to 0.2 μm, Fₘₐₓ will drop from above 100 G to only 60 G, which is a great loss, but the advantage of using a larger width is that a lower-level lithography machine and reticle can be used, which can reduce costs. To effectively increase the Fₘₐₓ while still using a low-cost process, the width of the emitter window dielectric layer must be reduced, or the doping concentration of the P-type SiGe epitaxial layer in the base region must be increased.

### SUMMARY OF THE INVENTION

An objective of the present invention is to provide a manufacturing method of a SiGe HBT, which can further reduce the base resistance of the device and improve its frequency characteristic without needing to reduce its size.

To achieve the above-mentioned objective, the present invention provides a manufacturing method of a SiGe HBT, wherein, after an emitter region is formed, an ion implantation is performed with a tilt angle to a base region by using an extrinsic base ion implantation process; boron ions are implanted during the extrinsic base ion implantation with an implantation dose from 1e15 to 1e16 cm⁻², an implantation energy from 5 to 30 KeV, and a tilt angle from 5 to 30 degrees. The tilt angle of the extrinsic base ion implantation enables the implantation of P-type impurities into the part of the intrinsic base region at the bottom of the emitter window dielectric layer as well as the extrinsic base region, so that the base region excluding the part of the intrinsic base region in contact with the emitter region is entirely doped with P-type impurities.

In a preferred embodiment, the manufacturing method of a SiGe HBT of the present invention comprises the following steps:

step 1: forming field oxide trenches and an active area in a P-type silicon substrate.

step 2: forming pseudo buried layers at the bottom of the field oxide trenches on both sides of the active area by N-type ion implantation, wherein each of the pseudo buried layers is separated by a lateral distance from the active area; the breakdown voltage of the SiGe HBT is adjustable by adjusting the lateral distance between the pseudo buried layers and the active area; the N-type ion implantation performed to form the pseudo buried layers has the following process conditions: the implantation dose is from 1e14 cm⁻²˜1e16cm⁻², and the implantation energy is from 1 KeV to 100 KeV.

step 3: tilling silicon oxide into the field oxide trenches to form field oxide regions.

step 4: performing an N-type ion implantation to the active area to form a collector region, wherein the depth of the collector region is larger than that of the bottom of the field oxide regions; the collector region laterally extends into the bottom of the field oxide regions on both sides of the active area and forms a contact with the pseudo buried layers; the N-type ion implantation performed to form the collector region has the following process conditions: the implantation dose is from 1e12 to 5e14 cm⁻², and the implantation energy is from 50 to 500 KeV.

step 5: forming a base window dielectric layer on the silicon substrate; etching part of the base window dielectric layer on top of the active area to form a base window which has a size larger than or equal to that of the active area; growing a P-type silicon-germanium epitaxial layer both on the silicon substrate in the base window and on the base window dielectric layer and forming a base region by etching; the base region in the base window is an intrinsic base region which forms a contact with the collector region; the base region outside the base window is an extrinsic base region which is isolated from the field oxide regions by the base window dielectric layer; the step of forming the base window dielectric layer further comprises: forming a first layer silicon oxide film on the silicon substrate; forming a second layer polysilicon film on the first layer silicon oxide film; the P-type silicon-germanium epitaxial layer is boron doped, and the doping concentration is from 1e19 to 1e20 cm⁻³; the boron doping is performed by using an ion implantation process with such conditions that the implantation dose is from 1e14 cm⁻²˜1e16 cm⁻² and the implantation energy is from 1 to 50 KeV; germanium has a trapezoidal or triangular distribution.

step 6: forming an emitter window dielectric layer on the intrinsic base region; etching the emitter window dielectric layer to form an emitter window which has a site smaller than that of the active area; growing an N-type polysilicon both on top of the intrinsic base region in the emitter window and on the emitter Window dielectric layer and forming an emitter region by etching; a part of the emitter region in the emitter window forms a contact with the intrinsic base region, and the other part of the emitter region outside the emitter window is isolated from the intrinsic base region by the emitter window dielectric layer: the step of forming the emitter window dielectric layer further comprises: forming a third layer silicon oxide film on the P-type silicon-germanium epitaxial layer; forming a fourth layer silicon nitride film on the third layer silicon oxide film; the N-type polysilicon of the emitter region is doped by using an N-type ion implantation process with such conditions that the implantation dose is from 1e14 cm⁻²˜1e16cm⁻² and the implantation energy is from 10 to 200 KeV.

step 7: performing an extrinsic base ion implantation with a tilt angle which enables the implantation of P-type impurities into the part of the intrinsic base region at the bottom of the emitter window dielectric layer as well as the extrinsic base region, so that the base region excluding the part of the intrinsic base region in contact with the emitter region is entirely doped with P-type impurities; boron ions are implanted during the extrinsic base ion implantation with an implantation dose from 1e15 to 1e16 cm⁻², an implantation energy from 5 to 30 KeV, and a tilt angle from 5 to 30 degrees.

step 8: forming a deep hole contact on top of each pseudo buried layer through the respective field oxide region to pick up an electrode of the collector region; the deep hole contact is formed by first forming a deep hole on top of each pseudo buried layer through the respective field oxide region, and then depositing a titanium/titanium nitride harrier metal layer in the deep hole and tilling tungsten into the deep hole; finally, the method further comprises forming silicide on the surface of the emitter region and the extrinsic base region.

Compared to the existing process which adopts a vertical implantation in the extrinsic base ion implantation, the present invention adopts a large tilt angle implantation in the extrinsic base ion implantation, which enables the implantation of boron ions directly into the base region at the bottom of the emitter window dielectric layer, namely, enables the base region excluding the part of the intrinsic base region in contact with the emitter region to be entirely doped with P-type impurities, so as to greatly reduce the r_{b} of the transistor and improve its Fₘₐₓ.

### BRIEF DESCRIPTION OF THE DRAWINGS

The present invention will be further described and specified by using figures and implementation details as follows:

FIG. 1 is a cross-sectional view showing the structure of an existing SiGe HBT;

FIG. 2 is a flow chart showing the method of the embodiment of the present invention;

FIG. 3 to FIG. 14 are schematic views showing the structures of the SiGe HBT in steps of the method of the embodiment of the present invention.

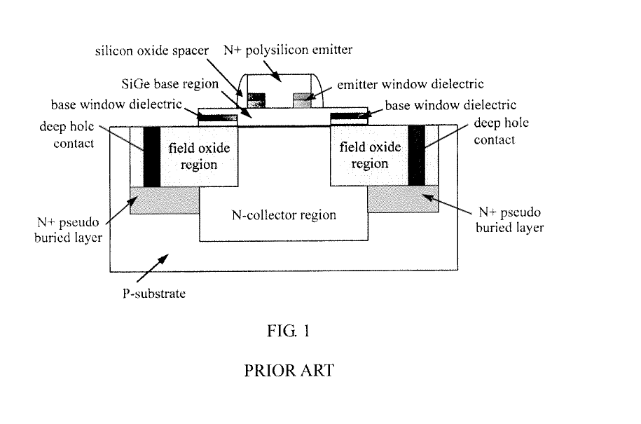

### DETAILED DESCRIPTION OF THE INVENTION

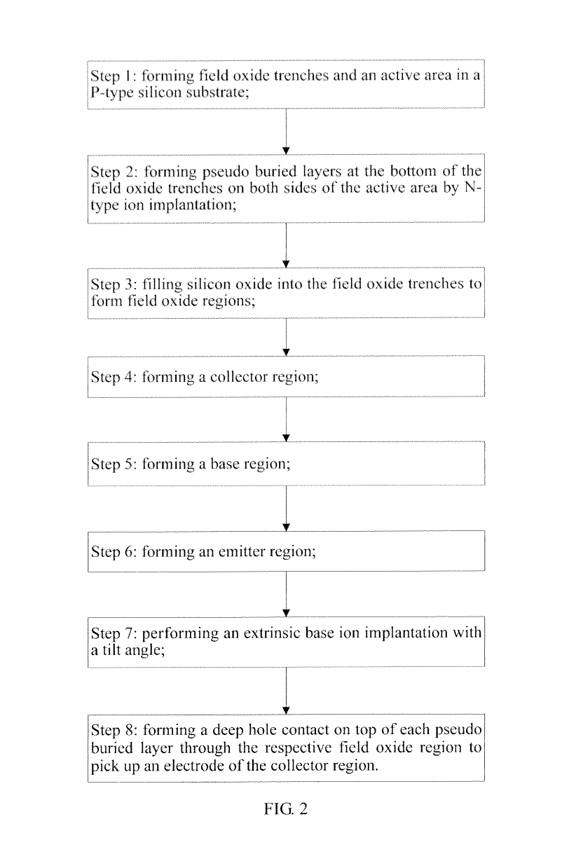

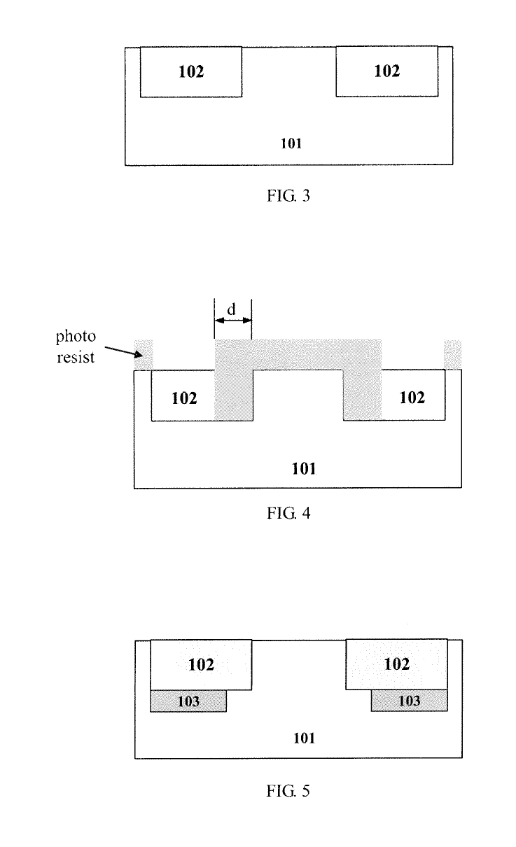

The flow chart FIG. 2 shows the method of the embodiment of the present invention, while schematic views FIG. 3 to FIG. 14 show the structures of the SiGe HBT in steps of the method of the embodiment of the present invention.

The manufacturing method of the SiGe HBT of the embodiment of the present invention comprises the following steps:

step 1: forming trenches of field oxide regions 102 and an active area in a P-type silicon substrate 101, as shown in FIG. 3.

step 2: forming pseudo buried layers 103, by first determining the areas of the pseudo buried layers 103 by using a photoetching method as shown in FIG. 4, namely, forming pseudo buried layer implantation windows by using photo resist, wherein the edge of each pseudo buried layer implantation window is separated by a lateral distance d from the edge of the active area; the breakdown voltage of the SiGe HBT is adjustable by adjusting the lateral distance d; and then forming the pseudo buried layers 103 by N-type ion implantation through the pseudo buried layer implantation windows into the bottom of the field oxide regions 102 on both sides of the active area as shown in FIG. 5, wherein each of the formed pseudo buried layers 103 is separated by a lateral distance d from the active area in a lateral direction and the lateral position of each pseudo buried layer s determined by the respective pseudo buried layer implantation window; process conditions of the N-type ion implantation performed to form the pseudo buried layers are as follows: the implantation dose is from 1e14 cm⁻²˜1e16cm⁻², and the implantation energy is from 1 to 100 KeV.

step 3: filling silicon oxide into the trenches of the field oxide regions 102 to form field oxide regions 102, as shown in FIG. 5.

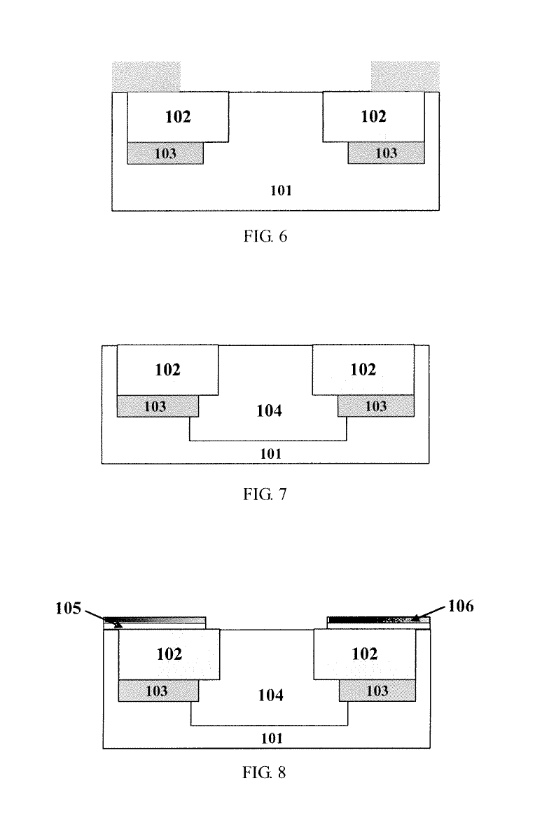

step 4: forming a collector region 104, by first determining an area of the collector region 104 by using a photoetching method as shown in FIG. 6, namely, forming a collector region implantation window by using photo resist; then forming the collector region 104 by performing an N-type ion implantation to the active area through the collector region implantation window as shown in FIG. 7, wherein the depth of the collector region 104 is larger than that of the bottom of the field oxide regions 102, and the collector region 104 laterally extends into the bottom of the field oxide regions 102 on both sides of the active area; the collector region 104 overlaps and forms a good contact with the pseudo buried layers 103; at last, a thermal well drive-in process is performed; process conditions of the N-type ion implantation performed to form the collector region 104 are as follows: the implantation dose is from 1e12 to 5e14 cm⁻², and the implantation energy is from 50 to 500 KeV.

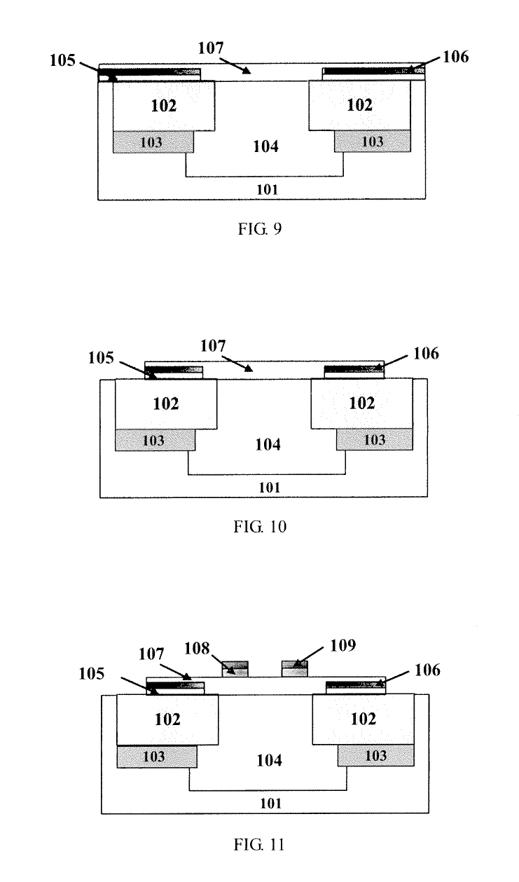

step 5: forming a base region 107, by first forming a base window dielectric layer as shown in FIG. 8, wherein the step further comprises: forming a first layer silicon oxide film 105 on the silicon substrate 101 and forming a second layer polysilicon film 106 on the first layer silicon oxide film 105; then etching part of the base window dielectric layer, namely the first layer silicon oxide film 105 and the second layer polysilicon film 106 on top of the active area, to form a base window which has a size larger than or equal to that of the active area to ensure that the SiGe epitaxial layer of the base region to be formed on top of the active area is a single crystal layer; then growing a P-type SiGe epitaxial layer on the silicon substrate 101 as shown in FIG. 9; then forming the base region 107 by etching the parts of both the P-type SiGe epitaxial layer and the base window dielectric layer outside the base region 107 as shown in FIG. 10; the part of the base region formed on top of the active area is an intrinsic base region which forms a contact with the collector region 104; the other part of the base region formed on top of the field oxide regions 102 is an extrinsic base region which is isolated from the field oxide regions 102 by the base window dielectric layer wherein the base window dielectric layer can reduce the junction capacitance between the extrinsic base region and the collector region; the P-type SiGe epitaxial layer is boron doped; the boron doping is performed by using an ion implantation process with such conditions that the implantation dose is from 1e14 cm⁻²˜1e16 cm⁻² and the implantation energy is from 1 to 50 KeV; germanium has a trapezoidal or triangular distribution.

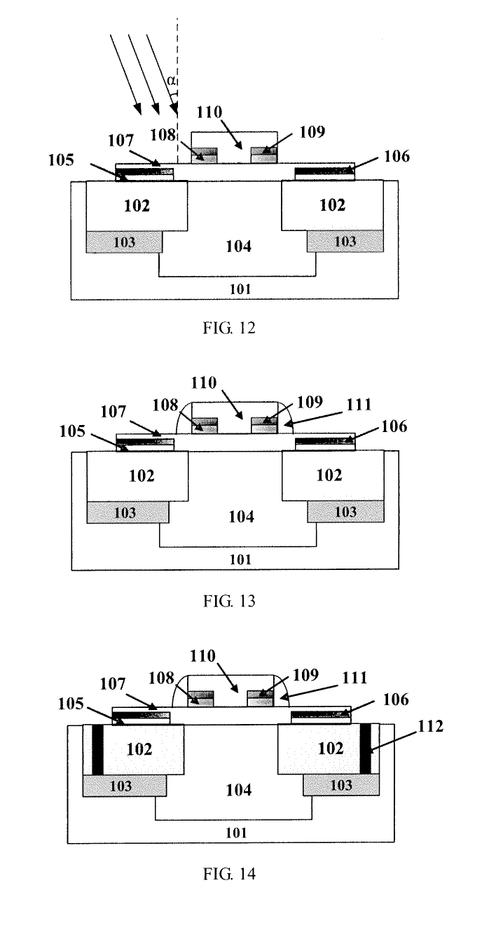

step 6: forming an emitter region 110, by first forming an emitter window dielectric layer as shown in FIG. 11, wherein the step further comprises: forming a third layer silicon oxide film 108 on the P-type SiGe epitaxial layer of the base region 107 and forming a fourth layer silicon nitride film 109 on the third layer silicon oxide film 108; then etching part of the emitter window dielectric layer, namely the third layer silicon oxide film 108 and the fourth layer silicon nitride film 109 on top of the intrinsic base region, to form an emitter window which has a size smaller than that of the active area to avoid influence to the intrinsic BE (base-emitter) junction caused by the part of the P-type silicon-germanium epitaxial layer at the edge of the active area with relatively poor quality of epitaxy; then growing an N-type polysilicon on top of the intrinsic base region and forming the emitter region 110 by etching as shown in FIG. 12, wherein, a part of the emitter region 110 in the emitter window forms a contact with the intrinsic base region, and the other part of the emitter region 110 outside the emitter window is isolated from the intrinsic base region by the emitter window dielectric layer; the N-type polysilicon of the emitter region is doped by using an N-type ion implantation process with such conditions that the implantation dose is from 1e14 cm⁻²˜1e16 cm⁻² and the implantation energy is from 10 to 200 KeV.

step 7: performing an extrinsic base ion implantation with a tilt angle α as shown in FIG. 12, to enable the implantation of P-type impurities into the part of the intrinsic base region at the bottom of the emitter window dielectric layer as well as the extrinsic base region, so that the base region 107 excluding the part of the intrinsic base region in contact with the emitter region 110 is entirely doped with P-type impurities; boron ions are implanted during the extrinsic base ion implantation with an implantation dose from 1e15 to 1e16 cm⁻², an implantation energy from 5 to 30 KeV, and a tilt angle α from 5 to 30 degrees.

step 8: forming silicon oxide spacers 111 of the emitter region 110 as shown in FIG. 13 wherein the silicon oxide spacers 111 can avoid short-circuit between the silicide of the emitter region 110 and the silicide on the extrinsic base growing silicide on the emitter region 110 and the extrinsic base region to reduce parasitic resistance; forming a deep hole contact 112 on top of each pseudo buried layer 103 through the respective field oxide region 102 to pick up an electrode of the collector region 104 as shown in FIG. 14; the deep hole contact 112 is formed by first forming a deep hole on top of the pseudo buried layer 103 in the field oxide region 102, and then depositing a titanium/titanium nitride barrier metal layer in the deep hole and filling tungsten into the deep hole; processes to form contact holes of the extrinsic base region and the emitter region 110, as well as other processes are further comprised.

While the present invention has been particularly shown and described with reference to the above embodiments thereof, it will be understood by those skilled in the art that various changes in form and details may be made without departing from the spirit and scope of the invention.

What is claimed is:

1. A manufacturing method of a silicon-germanium heterojunction bipolar transistor, wherein, after an emitter region is firmed, an ion implantation is performed with a tilt angle to a base region by using an extrinsic base ion implantation process; boron ions are implanted during the extrinsic base ion implantation with an implantation dose from 1e15 to 1e16 cm⁻², an implantation energy from 5 to 30 KeV, and a tilt angle from 5 to 30 degrees.

2. The method according to claim 1, comprising the following steps:
step 1: forming field oxide trenches and an active area in a P-type silicon substrate;
step 2: forming pseudo buried layers at the bottom of the field oxide trenches on both sides of the active area by N-type ion implantation, wherein each of the pseudo buried layers is separated by a lateral distance from the active area, the breakdown voltage of the silicon-germanium heterojunction bipolar transistor being adjustable by adjusting the lateral distance between the pseudo buried layers and the active area;
step 3: filling silicon oxide into the field oxide trenches to form field oxide regions;
step 4: performing an N-type ion implantation to the active area to form a collector region, wherein the depth of the collector region is larger than that of the bottom of the field oxide regions; the collector region laterally extends into the bottom of the field oxide regions on both sides of the active area and forms a contact with the pseudo buried layers;
step 5: forming a base window dielectric layer on the silicon substrate; etching part of the base window dielectric layer on top of the active area to form a base window which has a size larger than or equal to that of the active area; growing a P-type silicon-germanium epitaxial layer both on the silicon substrate in the base window and on the base window dielectric layer and forming a base region by etching; the base region in the base window is an intrinsic base region which forms a contact with the collector region; the base region outside the base window is an extrinsic base region which is isolated from the field oxide regions by the base window dielectric layer;
step 6: forming an emitter window dielectric layer on the intrinsic base region; etching the emitter window dielectric layer to form an emitter window which has a size smaller than that of the active area; growing an N-type polysilicon both on top of the intrinsic base region in the emitter window and on the emitter window dielectric layer and forming an emitter region by etching; a part of the emitter region in the emitter window forms a contact with the intrinsic base region, and the other part of the emitter region outside the emitter window is isolated from the intrinsic base region by the emitter window dielectric layer;
step 7: performing an extrinsic base ion implantation with a tilt angle, wherein boron ions are implanted during the extrinsic base ion implantation with an implantation dose from 1e15 to 1e16 cm⁻², an implantation energy from 5 to 30 KeV, and a tilt angle from 5 to 30 degrees;
step 8: forming a deep hole contact on top of each pseudo buried layer through the respective field oxide region to pick up an electrode of the collector region.

3. The method according to claim 2, wherein the N-type ion implantation performed to form the pseudo buried layers in step 2 has the following process conditions: the implantation dose is from 1e14 cm⁻²˜1e16 cm⁻², and the implantation energy is from 1 KeV to 100 KeV.

4. The method according to claim 2, wherein the N-type ion implantation performed to form the collector region in step 4 has the following process conditions: the implantation dose is from 1e12 to 5e14 cm⁻², and the implantation energy is from 50 to 500 KeV.

5. The method according to claim 2, wherein the step of forming the base window dielectric layer in step 5 further comprises: forming a first layer silicon oxide film on the silicon substrate: forming a second layer polysilicon film on the first layer silicon oxide film.

6. The method according to claim 2, wherein the P-type silicon-germanium epitaxial layer in step 5 is boron doped, and the doping concentration is from 1e19 to 1e20 cm⁻³; the boron doping is performed by using an ion implantation process with such conditions that the implantation dose is from 1e14 cm⁻²˜1e16 cm⁻² and the implantation energy is from 1 to 50 KeV: germanium has a trapezoidal or triangular distribution.

7. The method according to claim 2, wherein the step of forming the emitter window dielectric layer in step 6 further comprises: forming a third layer silicon oxide film on the P-type silicon-germanium epitaxial layer; forming a fourth layer silicon nitride film on the third layer silicon oxide film.

8. The method according to claim 1, wherein the N-type polysilicon of the emitter region in step 6 is doped by using an N-type ion implantation process with such conditions that the implantation dose is from 1e14 cm⁻²˜1e16 cm⁻² and the implantation energy is from 10 to 200 KeV.

9. The method according to claim 2, wherein, in step 8, the deep hole contact is formed by first forming a deep hole on top of each pseudo buried layer through the respective field oxide region, and then depositing a titanium/titanium nitride barrier metal layer in the deep hole and filling tungsten into the deep hole.

10. The method according to claim 2, further comprising: forming silicide on the surface of the emitter region and the extrinsic base region.
